(19) United States
(12) Patent Application Publication
(10) Pub. No.: US 2025/0098036 A1
(43) Pub. Date: Mar. 20, 2025

(54) METHOD FOR MANUFACTURING ELECTROSTATIC CHUCK

(71) Applicants: BOBOO HI-TECH CO., LTD., Yongin-si, Gyeonggi-do (KR); SAMSUNG ELECTRONICS CO., LTD., Suwon-si, Gyeonggi-do (KR)

(72) Inventors: Yun Hwi Park, Yongin-si (KR); Jin Yeol Wang, Yongin-si (KR); Yong Seok Choi, Yongin-si (KR); Ji Ho Uh, Hwaseong-si (KR); Seung Min Ryu, Hwaseong-si (KR); Do Youn Kim, Hwaseong-si (KR); Yoon Ho Jung, Hwaseong-si (KR)

(21) Appl. No.: 18/427,998

(22) Filed: Jan. 31, 2024

(30) Foreign Application Priority Data
Sep. 14, 2023 (KR) 10-2023-0122273

(51) Int. Cl. H05B 3/28; H01L 21/683; H05B 3/00

(52) U.S. Cl. CPC H05B 3/283; H01L 21/6833; H05B 3/0047

(57) ABSTRACT

The present invention relates to a method for manufacturing an electrostatic chuck, and more specifically, to a method for manufacturing an electrostatic chuck with minimized temperature deviation. The method of the present invention includes: a step S10 of forming a metal layer by depositing metal on a lower portion of a base containing a ceramic material and provided with an ESC electrode at an upper portion thereof; and a step S20 of forming a heater electrode by forming a pattern on the metal layer using a photolithography process.

### BACKGROUND OF THE INVENTION

The present invention relates to a method for manufacturing an electrostatic chuck, and more specifically, to a method for manufacturing an electrostatic chuck with minimized temperature deviation.

Among the semiconductor manufacturing processes, the semiconductor circuit manufacturing process is largely divided into substrate processing, wiring, and packaging. One of the most important processes in the substrate processing, so-called pre-processing, is etching, which is the process of selectively removing the layers formed as a result of an oxidation process or a thin film deposition process. The etching process uses physical action by ion shock onto the layer surface, or chemistry action or physical-chemical action of reactants generated in the plasma. How uniform the etching rate is at various points on the wafer (uniformity) and how much layer is removed (etching rate) over a certain period of time are considered a key factor for overall yield improvement.

Recently, in the semiconductor process, a high-density plasma environment has been introduced according to line width miniaturization for high integration of circuits. As a result, new processes such as dry etching and plasma cleaning are introduced, and the need for precise control of the high temperature process is emerging.

Therefore, there is a need for a multi-functional electrostatic chuck that fixes the silicon wafer undergoing a process and controls the temperature of the wafer higher than before by adding a heater to the electrostatic chuck (ESC) used in the etching process during the conventional semiconductor circuit manufacturing process (see Korean Patent No. 10-2450476, referred to as Prior Art 1 hereinafter).

Meanwhile, Korean Patent Application Publication No. 10-2016-0124668 (referred to as Prior Art 2 hereinafter) relates to a ceramic heater and an electrostatic chuck. More specifically, Prior Art 2 discloses a process of printing each pattern on an alumina green sheet by a conventional screen printing method corresponding to the formation point of each electrode or heating element using the metalizing ink to form an adsorption electrode, zone heating element, and internal conductive layer.

However, when a heater electrode is formed bay a screen printing method as in the Prior Art 2 above, it is problematic that the substrate cannot not be heated uniformly due to temperature deviation caused by the presence of deviations in the line width and the thickness of the heater electrode.

### SUMMARY OF THE INVENTION

In order to solve the above-described problems, it is an object of the present invention to provide a method for manufacturing an electrostatic chuck capable of uniformly heating a wafer.

In addition, it is an object of the present invention to provide a method for manufacturing an electrostatic chuck capable of measuring resistance at the intermediate product stage before being manufactured as a finished product.

The present invention, aimed at solving the above-described problems, has the following configuration and features.

The method according to the present invention includes: a step S10 of forming a metal layer by depositing metal at the lower portion of a base containing ceramic material and having an ESC electrode at an upper portion thereof; and a step S20 of forming a heater electrode by forming a pattern on the metal layer using a photolithography process.

In addition, before the step S10, the method according to the present invention may further include a step S5 of manufacturing the base by applying pressure to a material for sintering containing a ceramic material at 1000° C. or higher.

In addition, the method according to the present invention may further include, after the step S20, a sintering step S30 including: a step S301 of placing an intermediate product P at the upper portion of the material for sintering containing the ceramic material wherein the intermediate product includes the base and the heater electrode provided at the lower portion of the base; and a step S302 of sintering the material for sintering and the intermediate product P placed at the upper portion of the material for sintering by applying pressure at a temperature of 1000° C. or higher.

In addition, the method according to the present invention may further include, before the step S30, a step S25 of measuring a resistance of the heater electrode by connecting an ohmmeter to the heater electrode.

In addition, after the step S20, the heater electrode includes: a contacting part; and a connecting part connected to the contacting part having a width smaller than that of the contacting part.

In addition, the base manufactured in the base manufacturing step S5 is provided with a cave-in groove at an the upper portion thereof, and the method of the present invention may further include, after the base manufacturing step S5, an ESC electrode forming step including: a filling step for filling the cave-in groove of the base with a conductive paste; and an installation step for installing the ESC electrode at the upper portion of the base.

In addition, the method of the present invention may further include: a sintering step S30 including: a step S301 of placing an intermediate product at an upper portion of the material for sintering containing the ceramic material, the intermediate product comprising the base and the heater electrode provided at the lower portion of the base; a step S302 for placing the material for sintering containing the ceramic material at the upper portion of the intermediate product provided with the ESC electrode; and a step S303 of sintering the material for sintering and the intermediate product placed at the upper portion of the material for sintering by applying pressure at a temperature of 1000° C. or higher after the step S20 after the step S20; and a perforation step S40 of perforating the lower portion of an insulator manufactured by sintering the material for sintering and the base in the sintering step S30 to form an insert groove extending from a lower portion of the insulator to the conductive paste.

The present invention having the above configuration and features has the effect of uniformly heating the wafer.

In addition, the present invention has the effect of enabling resistance measurement to be performed at the intermediate product stage before being manufactured as a finished product.

### BRIEF DESCRIPTION OF DRAWINGS

FIG. 1 is a flowchart schematically illustrating a method for manufacturing an electrostatic chuck according to an embodiment of the present invention.

FIG. 2 is a diagram schematically illustrating a method for manufacturing an electrostatic chuck according to an embodiment of the present invention.

FIG. 3 is a diagram illustrating a metal layer provided at the base.

FIG. 4 is a SEM (scanning electron microscope) photograph illustrating the base and the metal layer provided at the base.

FIG. 5 is a diagram illustrating a contacting part and a connecting part of a heater electrode.

FIG. 6 is a diagram illustrating an intermediate product wherein a heater electrode is formed according to an embodiment.

FIG. 7 is a cross-sectional view schematically illustrating an electrostatic chuck manufactured by the method for manufacturing an electrostatic chuck.

FIG. 8 is an SEM photo of the heater electrode inside the electrostatic chuck.

FIG. 9 is a diagram illustrating a process for measuring a resistance of the heater electrode of the electrostatic chuck.

FIG. 10 is a graph showing a deviation in the resistance of the heater electrode in the intermediate product.

FIG. 11 is a graph showing the deviation in the resistance of the heater electrode of the electrostatic chuck after the sintering step.

FIG. 12 is a diagram schematically illustrating an ESC electrode forming step and perforation step.

### DETAILED DESCRIPTION

Since the present invention may be subject to various changes and have various forms, aspects (or embodiments) will be described herein in detail. However, this is not intended to limit the present invention to a specific embodiment, and should be understood to include all changes, equivalents, and substitutes included in the spirit and technical scope of the present invention.

The terms used herein are merely to describe specific aspects (or embodiments), and are not intended to limit the present invention. Singular expressions include plural expressions unless the context clearly dictates otherwise. Herein, It should be understood that terms such as ˜include˜ or ˜constitute˜ are intended to indicate the presence of features, numbers, steps, operations, components, parts, or combinations thereof, but are not intended to exclude in advance the presence or addition of one or more other features, numbers, steps, operations, components, parts, or combinations thereof.

Unless defined otherwise, all terms used herein, including technical or scientific terms, have the same meaning as commonly understood by a person of ordinary skill in the technical field to which the present invention pertains. Terms defined in commonly used dictionaries should be interpreted as having a meaning consistent with the meaning in the context of the related technology, and unless explicitly defined herein, should not be interpreted in an ideal or excessively formal sense.

˜First˜, ˜Second˜, etc. herein are only used to distinguish different elements, and are not limited by the order of manufacture, and the names are used in the detailed description and claims may not be the same.

Throughout this specification, when a part is said to be “connected” to another part, this includes not only the case of being “directly connected” but also the case of being “indirectly connected” with another element therebetween.

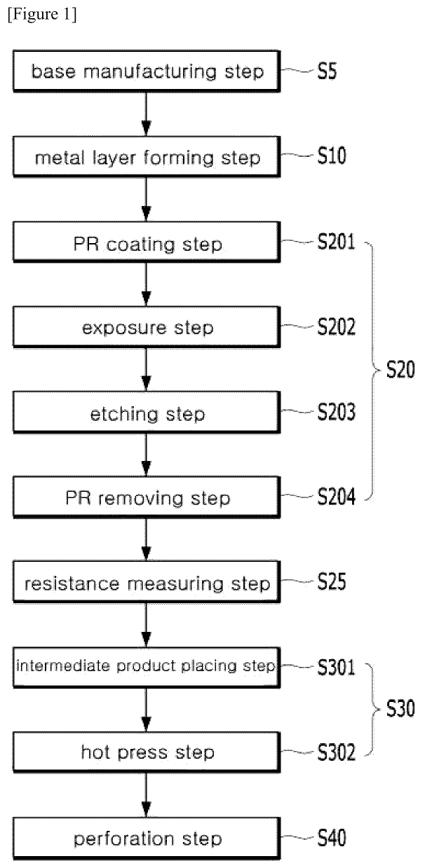

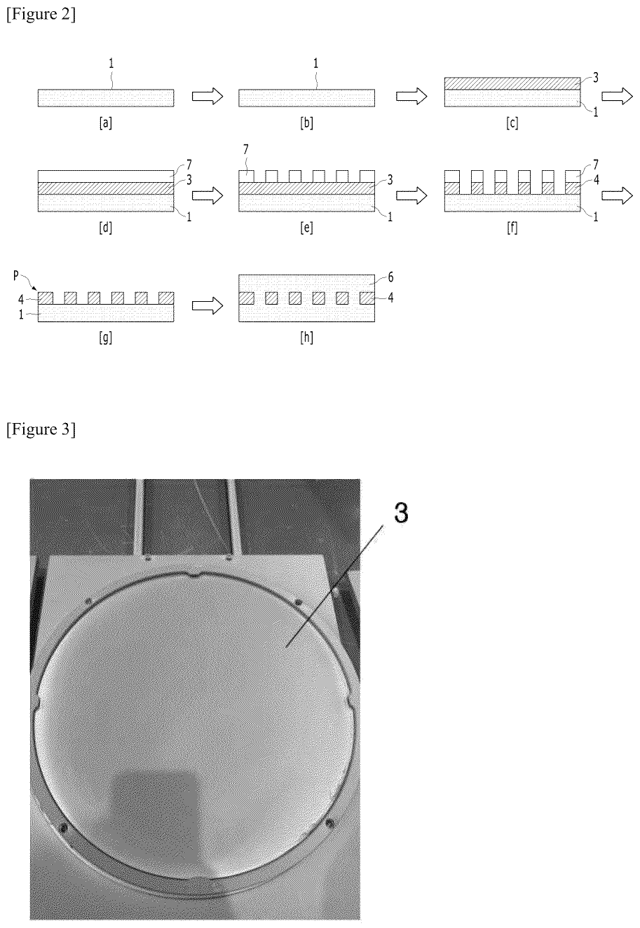

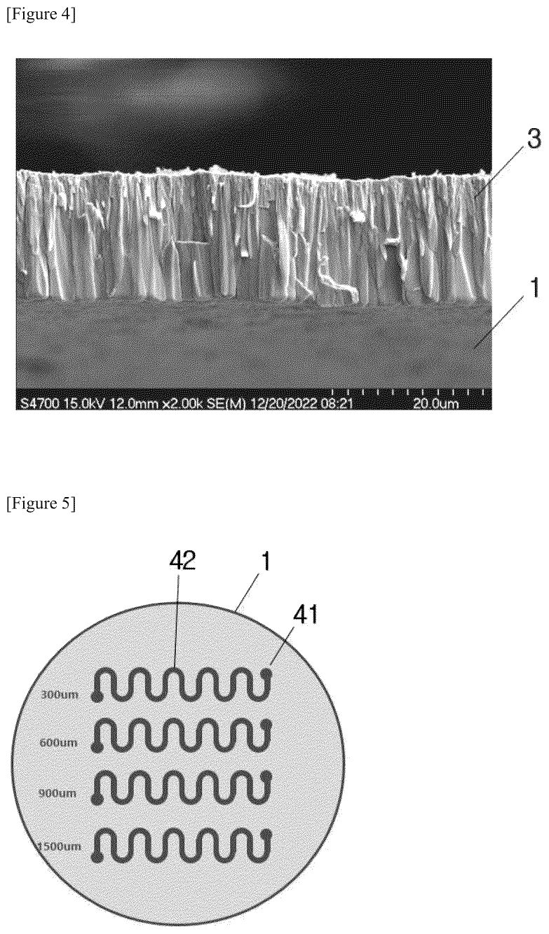

FIG. 1 is a flowchart schematically illustrating a method for manufacturing an electrostatic chuck according to an embodiment of the present invention. FIG. 2 is a diagram schematically illustrating a method for manufacturing an electrostatic chuck according to an embodiment of the present invention. FIG. 3 is a diagram illustrating a metal layer provided at the base. FIG. 4 is a SEM (scanning electron microscope) photograph illustrating the base and the metal layer provided at the base.

According to the method for manufacturing an electrostatic chuck of an embodiment of the present invention, an electrostatic chuck C capable of more uniformly heating wafers may be manufactured, and the measurement of a resistance of an intermediate product P is facilitated. Hereinafter, “the method for manufacturing an electrostatic chuck according to an embodiment of the present invention” will be referred to as “the method of the present invention” for convenience of explanation.

Referring to FIG. 1, the method of the present invention (the method for manufacturing an electrostatic chuck according to an embodiment of the present invention) includes a metal layer forming step S10 and a heater electrode manufacturing step S20.

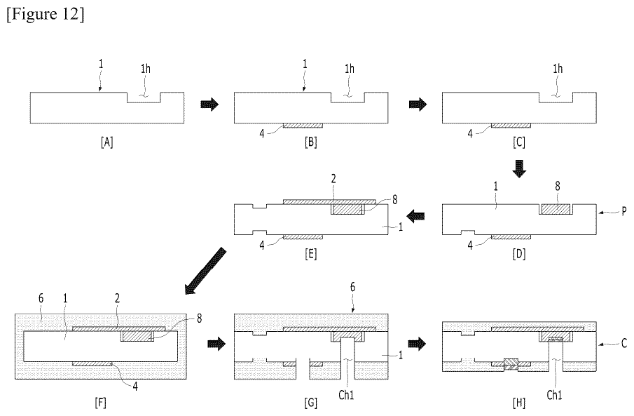

Referring to FIGS. 1 and 2, the metal layer forming step S10 includes a step for forming a metal layer 3 containing a ceramic material by depositing metal (e.g., tungsten) at a lower portion of a base 1 having thereon an ESC electrode 2 (referring to FIG. 12) is provided. This is the step of forming the metal layer 3.

Here, the lower portion (lower side, lower surface, lower end, etc.) refers to the lower portion (lower side, lower surface, lower end, etc.) of the electrostatic chuck C manufactured by the method of the present invention in the orientation shown in the cross-sectional view of FIG. 7, and, similarly, the upper portion (upper side, upper surface, upper end, etc.) refers to the upper portion (upper side, upper surface, upper end, etc.) in the orientation shown in FIG. 7. The same will be applied in the following.

Referring to FIGS. 1 and 2, the method of the present invention may include a base manufacturing step S5 (see [a] and [b] in FIG. 2) before the metal layer forming step S10 described above.

In the base manufacturing step S5, high pressure (20 MPa or higher) is applied to a raw material (material for sintering) containing a ceramic material (for example, alumina) at a temperature of 1000° C. or higher thereby sintering the raw material into the base 1.

Conventionally, a tape casting method was used to manufacture the base 1. According to the tape casting method, slurry containing a mixture of a ceramic material and a binder is spread thinly on a tape using a tape caster, water, etc. is then vaporized, and the tape is removed to manufacture a tape-type sheet.

The above-described sheets are laminated and the laminated sheets are sintered when the binder is evaporated to form the base 1, etc.

Meanwhile, the metal layer forming step S10 described later may include, for example, a sputtering method using plasma. In order to use the plasma, the inside of the chamber must be maintained in a vacuum state. However, when the sheet manufactured by the above-described tape casting method is used as glass of the sputtering method in the metal layer forming step S10 described later, the binder evaporates such that the inside of the chamber is difficult to be maintained in a vacuum state. Therefore, it is difficult to perform the metal layer forming step S10 described later.

That is, according to the method of the present invention, since the base 1 is manufactured using the base manufacturing method S5 (hot press method) rather than the tape casting method, the method of the present invention is advantageous in that maintaining the inner space of the chamber, etc. in a vacuum state during the metal layer forming step S10 described later is facilitated (in case the metal layer forming step S10 includes the sputtering method).

The metal layer forming step S10 described above is a step of forming a metal layer 3 by depositing metal on the base 1 manufactured in the base manufacturing step S5.

As described above, the metal layer forming step S10 may include a sputtering method. The general principle of sputtering is that an electric field is applied to the material to be deposited (target substance) and the portion to be coated with the film (base 1 corresponding to the glass portion) to generate plasma which is the fourth state of matter, therebetween, and, as the inert gas (for example, Ar+) moves toward the target substance connected to the negative pole to collide with the metal, causing the metal particles to bounce out and accumulate on the base 1 on the opposite side.

For example, the above-described target substance may include tungsten, and base 1 may include alumina.

As another example, the metal layer forming step S10 may include one or more of the above-described sputtering method, E-Beam deposition method, and thermal evaporation method, but is not limited thereto. That is, the metal layer forming step S10 may include various methods as long as the metal layer 3 is formed at the lower portion of the base 1.

After the metal layer forming step S10, the metal layer 3 (e.g., a tungsten layer) may be provided at the lower portion of the base 1 (see [c] in FIG. 2).

FIG. 3 is a diagram illustrating the base 1 provided with the metal layer 3, and FIG. 4 is a SEM photograph illustrating the base 1 provided with the metal layer 3 after the metal layer forming step S10. Referring to FIGS. 3 and 4, it may be seen that the metal layer 3 is provided at the lower portion of the base 1 after the metal layer forming step S10.

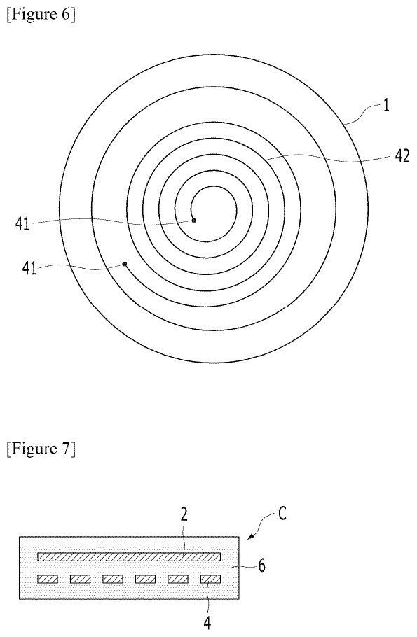

FIG. 5 is a diagram illustrating a contacting part and a connecting part of a heater electrode. FIG. 6 is a diagram illustrating an intermediate product wherein a heater electrode is formed according to an embodiment.

Referring to FIGS. 1 and 2, the heater electrode manufacturing step S20 includes a step of manufacturing a heater electrode 4 by forming a pattern on the metal layer 3 using a photolithography process.

Referring to FIG. 2 to describe the heater electrode manufacturing step S20 in more detail, the heater electrode manufacturing step S20 may include a step S201 of coating PR (photoresist) at the lower portion of the metal layer 3 (see [d] in FIG. 2).

In FIG. 2, while the metal layer 3 is provided at the upper portion of the base 1, and the PR is coated at the upper portion of the metal layer 3, the description is based on the orientation shown in FIG. 7 illustrating a cross-sectional view of the electrostatic chuck C manufactured by the method of the present invention wherein the ESC electrode 2 is disposed above the heater electrode 4.

After step S201, a PR layer 7 may be provided at the lower portion of the metal layer 3.

The heater electrode manufacturing step S20 may include a step S202 of patterning the PR layer 7 by placing a photo mask with a pattern at the lower portion of the PR layer 7 and irradiating light (exposure)(see [e] in FIG. 2).

In addition, the heater electrode manufacturing step S20 may include an etching step S203 of manufacturing the heater electrode 4 by selectively exposing (corroding) the metal layer 3 with a reactive gas, ion or etching solution through the portion where the PR layer 7 is removed to form a pattern on the metal layer 3.

In the above-described etching step S203, known techniques in various fields such as conventional reactive gases, ions and etching solutions may be used.

Lastly, the heater electrode manufacturing step S20 may include a step S204 of removing the PR layer 7.

Referring to FIGS. 5 and 6, after the above-described step S20, an intermediate product P provided with a heater electrode 4 at the lower portion of the base 1 may be manufactured.

Although not shown, the method of the present invention may include a step of installing an ESC electrode 2 at the upper portion of the base 1 after the base manufacturing step S5 (hereinafter referred to as an ESC electrode installation step).

Since the ESC electrode installation step is a known technology, more detailed description will not be given.

Conventionally, a screen printing method was used to install the heater electrode 4 on the base 1.

According to the conventional screen printing method, a polymer is applied and dried on a woven mesh to form a pattern, and the paste (containing metal, for example) that is the material of the heater electrode 4 is passed through the mesh to form a heater electrode on the base as a pattern.

However, when installing the heater electrode 4 using the screen printing method, the paste flows due to fluidity or passes through the mesh hole, leaving a mark (for example, a mesh mark), and the paste passed through the mesh hole forms a wave due to the adhesive force with the mesh, resulting in deviations in line width and thickness, which causes a problem of temperature deviation in the electrostatic chuck C.

Therefore, it is difficult to uniformly heat the wafer placed on the electrostatic chuck C.

However, according to the method of the present invention, the metal layer 3 is formed on the base 1 through the metal layer forming step 10 and is then etched to form the heater electrode 4 rather than installing a patterned heater electrode 4 on the base 1 through the screen printing method. Therefore, the thickness/line width of the heater electrode 4 may be relatively uniform compared to the above-described screen printing method, thereby advantageously minimizing the temperature deviation of the chuck C.

Referring to FIGS. 1 and 7, the method of the present invention may include a resistance measuring step S25 performed after the heater electrode manufacturing step S20 and before the sintering step S30 described later.

The resistance measuring step S25 includes a step of measuring the resistance of the heater electrode 4 by connecting an ohmmeter to the heater electrode 4.

Various known ohmmeters used in the relevant field may be used as the above-mentioned ohmmeter.

Conventionally, the above-described heater electrode 4 is manufactured using the screen printing method. In the screen printing method described above, a paste mixed with metal and binder passes through the mesh and attaches to the base 1, which causes the resistance of the heater electrode 4 to be excessively high before the evaporation of the binder occurring during the sintering process. Therefore, it is difficult to precisely measure the resistance of the heater electrode 4 before the sintering process.

However, the method of the present invention includes the above-described base manufacturing step S5, metal layer forming step S10, and heater electrode manufacturing step S20 rather than the screen printing method such that the resistance of the heater electrode 4 may be measured precisely through a resistance measuring step S25 even before the sintering step S30 to be described later.

Therefore, before sintering, it is possible to measure the resistance of the intermediate product P manufactured in the heater electrode manufacturing step S20 of the method of the present invention and defective products may be identified discarded before the sintering step S30, thereby significantly reducing the manufacturing costs.

Meanwhile, referring to FIG. 5, the heater electrode 4 manufactured in the heater electrode manufacturing step S20 may include a pair of contacting parts 41 and a connecting part 42 connecting the pair of contacting parts 41.

The contacting parts 41 and the connecting part 42 described above may correspond to the pattern of the photo mask on which a pattern corresponding to the pattern of the PR layer 7 described later is provided.

That is, in the heater electrode manufacturing step S20 described above, the photo mask may include a first cover portion having a shape corresponding to the pair of contacting parts 41 and a second cover portion having a shape corresponding to the connecting part 42.

Here, the width of the connecting part 42 may be narrower than that of the contacting part 41. For example, when the contacting part 41 have a circular shape, and the connecting part 42 have a linear shape, the width of the contacting part 41 may refer to the diameter, and the width of the connecting part 42 may refer to width or thickness perpendicular to the lengthwise direction thereof on a plane.

As described above, the width of the contacting part 41 is formed to be larger than that of the connecting part 42 so as to facilitate the electrical connection with pins or wires connected to the ohmmeter.

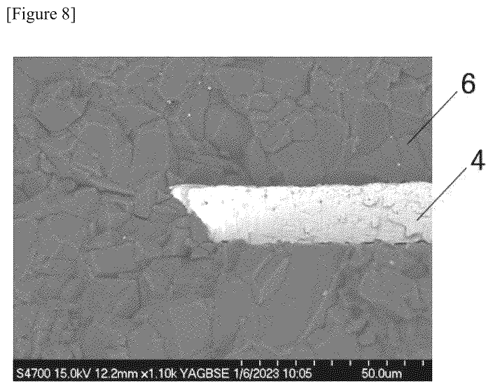

FIG. 7 is a cross-sectional view schematically illustrating an electrostatic chuck manufactured by the method for manufacturing electrostatic chuck. FIG. 8 is an SEM photo of the heater electrode inside the electrostatic chuck.

Referring to FIGS. 1 and 8, the method of the present invention, after the step S20, may include a sintering step S30 including: a step S301 of placing an intermediate product P at the upper portion of the material for sintering containing the ceramic material wherein the intermediate product includes the base 1 and the heater electrode 4 provided at the lower portion of the base 1; and a step S302 of sintering the material for sintering and the intermediate product P placed at the upper portion of the material for sintering by applying high pressure (20 MPa or higher) at a temperature of 1000° C. or higher.

In the sintering step S30, the base 1 and the material for sintering are sintered to form the insulator 6, and the heater electrode 4 is built into the insulator 6, thereby forming an electrostatic chuck C. (See [h] in FIG. 2 and FIG. 7).

As described above, the ESC electrode 2 may be provided at the upper portion of the base 1. However, the material for sintering may also be placed at the upper portion of the base 1 such that the ESC electrode 2 is also built into the insulator 6 in the sintering step S30.

Meanwhile, the planar cross-sectional area of the inner space of the mold performing the sintering step S30 is preferably larger than the dimension (planar cross-sectional area) of the intermediate product P, thereby suppressing the occurrence of cracks of the insulator 6 caused by the difference in thermal expansion coefficient.

Meanwhile, in the step S301 described above, the height of the base 1 may be equal to that of the material for sintering (material for sintering layer) provided at the lower portion of the base 1 or the height of the material for sintering (material for sintering layer) may be higher than that of the base 1. Accordingly, it is possible to prevent the insulator 6 from being damaged due to stress resulting from the asymmetric structure in the step S302.

Referring to FIG. 8, it may be seen that a heater electrode 4 is built into the insulator 6.

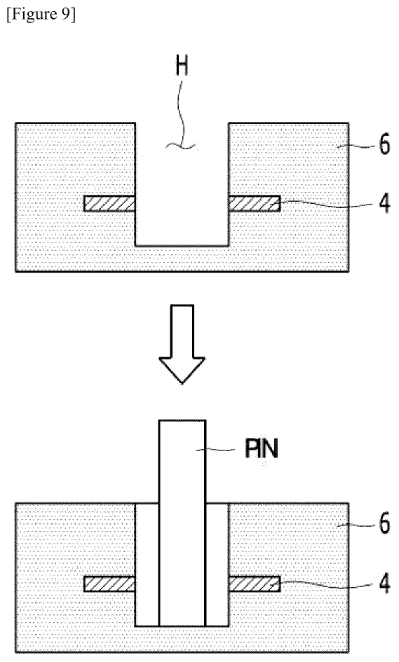

FIG. 9 is a diagram illustrating a process for measuring a resistance of the heater electrode of the electrostatic chuck.

Table 1 below shows the resistance (“Resistance after deposition” in Table 1 below) of the heater electrode 4 with different line widths (300 μm, 600 μm, 900 μm, 1500 μm) in the intermediate product P state, and the resistance (“Resistance after sintering” in Table 1 below) of the heater electrode 4 after the sintering step S30.

Referring to FIG. 9, the resistance of the heater electrode 4 of the electrostatic chuck C is measured through a second resistance measuring step including a step S40 of perforating the insulator 6 to form a groove H penetrating the heater electrode 4 (for example, the contacting part 41) (the resistance measuring step S25 may be a first resistance measuring step).

The second resistance measuring step may include a step S42 of inserting a pin PIN connected to an ohmmeter into the groove H and electrically connecting the pin PIN and the heater electrode 4 by bonding (for example, brazing); and a step S43 of measuring the resistance of the heater electrode 4 using the ohmmeter.

TABLE 1

| | W resistivity | | 52.8 | nΩ · m |
|---|---|---|---|---|
| Line width (μm) | 300 | 600 | 900 | 1500 |
| Thickness (μm) | 15 | 15 | 15 | 15 |
| Cross-sectional area (m²) | 4.5E−09 | 9E−09 | 1.35E−08 | 2.25E−08 |
| Length (m) | 2 | 2 | 2 | 2 |
| Expected resistance (Ω) | 23.5 | 11.7 | 7.8 | 4.7 |
| Resistance after | 203 | 120 | 99 | 68 |
| deposition (#1) | | | | |
| Resistance after | 28 | 16 | 12.5 | 7.9 |
| sintering (#2) | | | | |

Referring to Table 1 above, it may be seen that the resistance of the heater electrode 4 in all line widths decreases significantly after the sintering step S30.

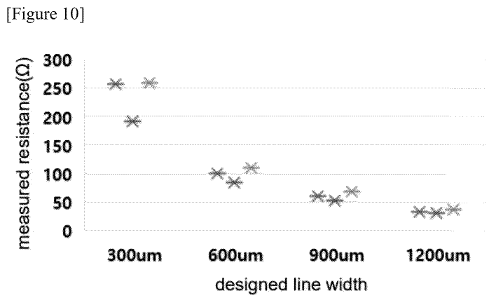

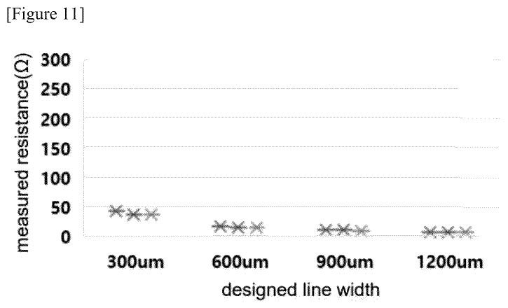

FIG. 10 is a graph showing a deviation in the resistance of the heater electrode in the intermediate product, and FIG. 11 is a graph showing the deviation in the resistance of the heater electrode of the electrostatic chuck after the sintering step.

Referring to FIG. 10, according to the result of the measurements of the resistances of a total of three (blue, red, and light green in FIGS. 10 and 11) heater electrodes 4 of the intermediate product P and the resistance of the heater electrode 4 of the electrostatic chuck C manufactured by the method of the present invention, it may be seen that the resistance deviation of the intermediate product P increases as the line width decreases (closer to 300 micrometers).

However, referring to FIG. 11, it may be seen that the resistances are reduced for all products after the sintering step S12, and the actual resistance is relatively uniform across all line widths.

FIG. 12 is a diagram schematically illustrating an ESC electrode forming step and perforation step.

Referring to FIG. 12, in the electrostatic chuck C manufactured by the method of the present invention, the heater electrode 4 or the ESC electrode 2 built inside the insulator 6 must be electrically connected to an external wire.

However, since the upper portion of the electrostatic chuck C is generally subjected to surface processing, the distance from the upper surface of the insulator 6 to the ESC electrode 2 in the electrostatic chuck C becomes shorter (for example, 50 to 500 μm). In such case, when perforating the upper portion of the ESC electrode 2 to electrically connect the ESC electrode 2 to the external wire, the problem of the distance between the upper surface of the insulator 6 and the ESC electrode 2 being too short occurs, resulting in cracks.

Therefore, recently, the lower portion of the ESC electrode 2 was perforated to electrically connect the lower portion of the ESC electrode 2 to the external wire by placing a conductor (including metal) to be in contact with the lower portion of the ESC electrode 2 and connecting an external wire to the conductor to prevent damage to the ESC electrode 2.

Therefore, according to the method of the present invention, the base 1 manufactured in the base manufacturing step S5 may include a cave-in groove 1h at the upper portion thereof and recessed downward (see FIG. 12). The cave-in groove 1h described above may be formed by perforating the upper portion of the sintered base 1, or by applying pressure to and molding the raw material at a high temperature in a sintering mold.

Here, conventionally, as described above, a conductor was inserted into the cave-in groove 1h and the ESC electrode 2 was installed thereon. In such case, it was problematic that cracks were generated due to the stress caused by the difference in thermal expansion coefficient in the sintering step S30 to be described later.

Therefore, in order to complement the conventional problem, the method of the present invention includes a process of filling the above-described cave-in groove 1h with a conductive paste rather than a conductor.

That is, the method of the present invention may include, after the base manufacturing step S5, an ESC electrode forming step including: a filling step (see [D] in FIG. 12) of filling the cave-in groove 1h of the base 1 with conductive paste; and an installation step (see [E] in FIG. 12) of installing an ESC electrode at the upper portion of the base 1.

The conductive described above paste generally refers to a conductive ink capable of flowing electricity which is a material manufactured by dispersing and mixing conductive metal powder in a fluid binder.

The conductive paste described above may be, for example, a high-temperature sintering paste and may contain metal powder such as tungsten, nickel, etc.

As the binder, a polymer organic binder is generally used. However, since the polymer organic binder thermally decomposes and vaporizes at high temperature, glass frit, which is an inorganic binder, may be used.

At high temperatures, glass frits and metal powder particles fuse together to form a single metal lump, which has the advantage of reducing the interfacial resistance between particles and increasing conductivity.

The conductive paste described above may include solvents, additives, etc. in addition to metal powder (for example, copper powder) and binder.

The conductive paste described above is well-known, and a more detailed description will be omitted. The above description is given as an example. As long as the conductive paste exists in paste form at room temperature, various configurations may be replaced or added to the above-described configurations.

The installation step of the ESC electrode forming step described above may be performed by various known methods, such as photolithography methods. Since this is a known technology, a more detailed description will be omitted.

It is preferable that the ESC electrode forming step described above is performed after the base manufacturing step S5 and before the resistance measuring step S25.

The ESC electrode forming step described above may be performed after step S20, but not limited thereto. The ESC electrode forming step may be performed before step S20 or simultaneously with step S20. Alternatively, The ESC electrode forming step may be performed before, after, or simultaneously with the metal layer forming step S10.

The sintering step S30 may include: an intermediate product placing step S301 of placing the intermediate product P at the upper portion of the material for sintering containing the ceramic material wherein the intermediate product P includes the base 1 and the heater electrode 4 provided at the lower portion of the base 1, and placing the material for sintering containing the ceramic material at the upper portion of the intermediate product P provided with the ESC electrode after the step S20.

In addition, the sintering step S30 may include a step S302 of sintering the material for sintering and the intermediate product P by applying high pressure (20 MPa or higher) at a temperature of 1000° C. or higher.

In the sintering step S30, the base 1 and the material for sintering are sintered to form the insulator 6, and the heater electrode 4 and the ESC electrode are built into the insulator 6, thereby forming an electrostatic chuck C. (See [F] in FIG. 12).

Thereafter, according to the method of the present invention, single lump of metal may be formed by perforating the lower portion of the insulator 6 of the electrostatic chuck C manufactured in the sintering step S30 and fusing the metal powder and the binder of the conductive paste at the lower portion of the insulator 6 at a high temperature.

When the volume of the base 1 and the material for sintering is decreased as the base 1 and the material for sintering are sintered, the volume of the metal powder and the binder is also decreased as the metal powder is fused to the binder. Therefore, the stress during the sintering process may be reduced, thereby suppressing the occurrence of cracks.

The method of the present invention may include a perforation step S40 of perforating the lower portion of the electrostatic chuck C (the lower portion of the insulator 6) manufactured in the sintering step S30 to form an insert groove Ch1 extending from the lower portion of the insulator 6 to the conductive paste (metal lump) (see [G] in FIG. 12).

The insert groove (Ch1) may be formed from the lower portion of the insulator 6 to the inside of the metal lump.

The perforation step S40 may include a step of perforating the lower portion of the electrostatic chuck C (lower portion of the insulator 6) to form an installation groove ch2 extending from the lower portion of the electrostatic chuck C (lower portion of the insulator 6) through the heater electrode 4 to the inside of the base 1.

The method of the present invention may include a step of subjecting the upper portion and the lower portion of the electrostatic chuck C to surface processing before or after the perforation step S40. The distance between the upper portion of the electrostatic chuck C and the upper portion of the ESC Electrode 2 is approximately 50 to 500 m. Here, since the above-described insert groove Ch1 is formed at the lower portion of the electrostatic chuck C rather than the upper portion of the electrostatic chuck C, the occurrence of cracks in the electrostatic chuck C is suppressed.

It apparent that the method of the present invention may include the step of inserting a terminal or rod connected to an external wire in the above-mentioned insert groove Ch1 and installation groove Ch2.

The present invention described above with reference to the accompanying drawings may be modified and changed by those skilled in the art in various ways, and such modifications and changes should be construed as falling within the scope of the present invention.

[DESCRIPTION OF REFERENCE NUMERALS]

| | |
|---|---|
| electrostatic chuck: C | intermediate product: P |
| base: 1 | ESC electrode: 2 |
| metal layer: 3 | heater electrode: 4 |
| contacting part: 41 | connecting part: 42 |
| insulator: 6 | PR layer: 7 |
| conductive paste: 8 | |
| pin: PIN | groove: H |

1. A method for manufacturing an electrostatic chuck, the method comprising:
a step S10 of forming a metal layer by depositing metal on a lower portion of a base containing a ceramic material and provided with an ESC electrode at an upper portion thereof; and
a step S20 of forming a heater electrode by forming a pattern on the metal layer using a photolithography process.

2. The method of claim 1, further comprising: a step S5 of manufacturing the base by applying pressure to a material for sintering containing the ceramic material at a temperature of 1000° C. or higher before the step S10.

3. The method of claim 1, further comprising a sintering step S30 comprising: a step S301 of placing an intermediate product at an upper portion of a material for sintering containing the ceramic material, the intermediate product comprising the base and the heater electrode provided at the lower portion of the base; and a step S302 of sintering the material for sintering and the intermediate product placed at the upper portion of the material for sintering by applying pressure at a temperature of 1000° C. or higher after the step S20.

4. The method of claim 3, further comprising: a step S25 of measuring a resistance of the heater electrode by connecting an ohmmeter to the heater electrode before the step S30.

5. The method of claim 1, wherein the heater electrode comprises: a contacting part; and a connecting part connected to the contacting part having a width smaller than that of the contacting part in the step S20.

6. The method of claim 2, wherein the base manufactured in the step S5 is provided with a cave-in groove at an the upper portion thereof, and
further comprising an ESC electrode forming step comprising: a filling step for filling the cave-in groove of the base with a conductive paste; and an installation step for installing the ESC electrode at the upper portion of the base after the step S5.

7. The method of claim 6, further comprising:
a sintering step S30 comprising: a step S301 of placing an intermediate product at an upper portion of the material for sintering containing the ceramic material, the intermediate product comprising the base and the heater electrode provided at the lower portion of the base; a step S302 for placing the material for sintering containing the ceramic material at the upper portion of the intermediate product provided with the ESC electrode; and a step S303 of sintering the material for sintering and the intermediate product placed at the upper portion of the material for sintering by applying pressure at a temperature of 1000° C. or higher after the step S20; and
a perforation step S40 of perforating the lower portion of an insulator manufactured by sintering the material for sintering and the base in the sintering step S30 to form an insert groove extending from a lower portion of the insulator to the conductive paste.
